(19) United States
(12) Patent Application Publication
(10) Pub. No.: US 2008/0104474 A1
(43) Pub. Date: May 1, 2008

(54) Low Density Parity Check (Ldpc) Decoder

(75) Inventors: Wen Gao, West Windsor, NJ (US); Kumar Ramaswamy, Princeton, NJ (US); John Sidney Stewart, Indianapolis, IN (US)

Correspondence Address: Joseph J. Laks;Thomson Licensing LLC, 2 Independence Way, Patent Operations, PO Box 5312, PRINCETON, NJ, 08543, US

(73) Assignee: Joseph J Laks, Princeton, NJ (US)

(21) Appl. No.: 11/662,565

(22) PCT Filed: Sep. 19, 2005
(86) PCT No.: PCT/US05/33342

§ 371 Date: Mar. 12, 2007

Related U.S. Application Data
(60) Provisional application No. 60/615,418, filed on Oct. 1, 2004.

(51) Int. Cl. H03M 13/05; G06F 11/10

(52) U.S. Cl. 714/752; 714/E11.032

(57) ABSTRACT

A satellite receiver comprises a front-end, demodulator and an LDPC decoder. The front-end receives a DVB-S2 LDPC coded signal and provides a down-converted signal to the demodulator. The latter demodulates the down-converted signal and provides a demodulated signal to the LDPC decoder. The LDPC decoder has a partially parallel architecture and partitions the bit node messages into N/360 groups and the check node messages into q groups, where q=M/360. Each group is processed by 360 bit node processors or 360 check node processors, respectively. Illustratively, the LDPC decoder includes a memory that is partitioned such that messages associated with bit node groups are consecutively addressed. Alternatively, the LDPC decoder includes a memory that is partitioned such that messages associated with check node groups are consecutively addressed.

### BACKGROUND OF THE INVENTION

The present invention generally relates to communications systems and, more particularly, to a receiver that processes low density parity check (LDPC) encoded data.

In recent years, LDPC codes have increased in popularity because of its near-Shannon limit error-correcting capability. For example, the second generation of digital video broadcast standard (DVB-S2) has adopted LDPC codes as the major error-correcting code replacing the convolutional codes used in the first generation DVB standards (e.g., see European Telecommunications Standards Institute (ETSI) Draft EN 302307, v.1.1.1, June 2004).

In general, an (N, K) LDPC code is a parity check code, where K is the number of bits to be encoded, N is the size (length) of the resulting coded block and (N-K) are the additional error correction bits added by the code. An (N, K) LDPC code can be expressed in matrix form as the set of solutions, x, of the following matrix equation: Hx^{T}=0^{T}. This equation is also referred to as the “parity check equation,” where the superscript T refers to the transpose of the associated matrix, and H is referred to as the “parity check matrix” having dimensions M×N, where N, as noted above, corresponds to the size of the resulting coded block and M=N−K. The modifier “low-density” conveys the fact that the fraction of nonzero elements in the parity check matrix, H, is small, and in particular it is linear in the code block length N. (In contrast, “random” linear block codes are those for which the expected number of ones grows on the order of N².)

As known in the art, an LDPC code can also be represented by a bipartite graph, which is useful for understanding the LDPC decoding process. In the context of the parity check matrix, H, having dimensions M×N, the corresponding bipartite graph contains N bit nodes (also called variable nodes or message nodes) corresponding to the N columns of the parity check matrix and also contains M check nodes corresponding to the M rows of the parity check matrix. Each check node connects to one, or more, bit nodes. Specifically, an edge (or a branch) connects a check node m to a variable node n if and only if H_{m,n}=1, where 0≦n<N and 0≦m<M. For a bipartite graph, the term “degree of the bit node” (or bit node degree) refers to the number of check nodes to which the bit node is connected. Similarly, the term “degree of the check node” (or check node degree) refers to the number of bit nodes to which the check node is connected. It should also be observed that the check node degree and the bit node degree also correspond to the number of “1”s in the respective rows and columns of the parity check matrix, H. Turning briefly to FIG. 1, an illustrative parity check matrix 5 and a corresponding bipartite graph 6 are shown, where N=7 and M=3. Illustratively, the bit node degree for bit node x₇ is one and the check node degree for check node c₃ is four.

As noted above, the bipartite graph is useful for understanding the LDPC decoding process. In this context, in the LDPC decoder a check node is associated with a check node processor and a bit node is associated with a bit node processor. Unfortunately, while the decoding algorithm for an LDPC decoder is conceptually simple, the architecture of an LDPC decoder for a large code block or a near-random parity check matrix poses significant implementation challenges. There are three known architectures for implementing an LDPC decoder. The first one is a fully parallel architecture, in which all the check nodes, bit nodes and their connections are mapped into hardware. This architecture results in a very high-speed decoder. However, this architecture is not practical for decoding LDPC codes with long block length due to high hardware complexity. The second one is a serial architecture, in which only one check node processing unit (CPU) and one bit node processing unit (BPU) are implemented and reused multiple times to accomplish all the decoding operations. Unfortunately, since all processing is done in a serial fashion, the serial architecture results in a decoder with very low speed. Finally, the third one is a partially parallel architecture, which is a middle ground between the first and second architectures. Here, multiple bit node processing units (BPUs) and multiple check node processing units (CPUs) are implemented and reused to, in effect, trade-off between hardware complexity and decoding latency for the desired LDPC decoder. Unfortunately, no consistent design approach exists for efficiently implementing a partially parallel LDPC decoder.

### SUMMARY OF THE INVENTION

We have observed that it is possible to reduce the complexity of an LDPC decoder by exploiting certain properties of LDPC parity check matrices and, thus, design a more efficient LDPC decoder having a partially parallel architecture. Therefore, and in accordance with the principles of the invention, a receiver performs an LDPC decoding method comprising the steps of: receiving LDPC encoded data; and processing the received LDPC encoded data to provide decoded data; wherein the processing step partitions the bit node messages into Y groups and the check node messages into q groups, where q varies as a function of the code rate.

In an embodiment of the invention, a satellite receiver comprises a front-end, a demodulator and an LDPC decoder. The front-end receives a DVB-S2 LDPC coded signal and provides a down-converted signal to the demodulator. The latter demodulates the down-converted signal and provides a demodulated signal to the LDPC decoder. The LDPC decoder has a partially parallel architecture and partitions the bit node messages into N/360 groups and the check node messages into q groups, where q=M/360. Each group is processed by 360 bit node processors or 360 check node processors, respectively. Illustratively, the LDPC decoder includes a memory that is partitioned such that messages associated with bit node groups are consecutively addressed.

In an embodiment of the invention, a satellite receiver comprises a front-end, a demodulator and an LDPC decoder. The front-end receives a DVB-S2 LDPC coded signal and provides a down-converted signal to the demodulator. The latter demodulates the down-converted signal and provides a demodulated signal to the LDPC decoder. The LDPC decoder has a partially parallel architecture and partitions the bit node messages into N/360 groups and the check node messages into q groups, where q=M/360. Each group is processed by 360 bit node processors or 360 check node processors, respectively. Illustratively, the LDPC decoder includes a memory that is partitioned such that messages associated with check node groups are consecutively addressed.

### BRIEF DESCRIPTION OF THE DRAWINGS

FIG. 1 illustrates a parity check matrix and a bipartite graph with respect to LDPC coding;

FIG. 2 shows Table One, which illustrates some DVB-S2 LDPC coding parameters;

FIGS. 3-5 shows some known observations about the DVB-S2 LDPC parity check matrices;

FIG. 6 shows Table Two which further illustrates some observations about DVB-S2 LDPC coding;

FIGS. 7-12 illustrate the reorganization of a parity check matrix in accordance with the principles of the invention;

FIG. 13 shows a portion of an illustrative communications system embodying the principles of the invention;

FIG. 14 shows an illustrative embodiment of a receiver in accordance with the principles of the invention;

FIG. 15 shows an illustrative embodiment of an LDPC decoder in accordance with the principles of the invention;

FIGS. 16 and 17 show an illustrative memory structure for use in the LDPC decoder in accordance with the principles of the invention;

FIG. 18 shows an illustrative flow chart in accordance with the principles of the invention for use in the LDPC decoder of FIG. 15;

FIG. 19 illustrates message passing with respect to the embodiment shown in FIG. 15;

FIG. 20 shows an illustrative memory structure for use in the LDPC decoder in accordance with the principles of the invention;

FIG. 21 illustrates the operation of a cyclic shifter of FIG. 15;

FIG. 22 shows an illustrative check node processing unit for use in the LDPC decoder of FIG. 15;

FIGS. 23 and 24 show an illustrative bit node processing unit for use in the LDPC decoder of FIG. 15;

FIGS. 25-28 show another illustrative embodiment in accordance with the principles of the invention; and

FIG. 29 shows another illustrative embodiment in accordance with the principles of the invention.

### DETAILED DESCRIPTION

Other than the inventive concept, the elements shown in the figures are well known and will not be described in detail. For example, other than the inventive concept, satellite transponders, downlink signals, symbol constellations, carrier recovery, interpolation, phase-locked loops (PLLs), a radio-frequency (rf) front-end, or receiver section, such as a low noise block downconverter, formatting and encoding methods (such as Moving Picture Expert Group (MPEG)-2 Systems Standard (ISO/IEC 13818-1), LDPC coding, etc.) for generating transport bit streams and decoding methods such as log-likelihood ratios, soft-input-soft-output (SISO) decoders, Viterbi decoders are well-known and not described herein. In addition, the inventive concept may be implemented using conventional programming techniques, which, as such, will not be described herein. Also, familiarity with satellite-based systems (e.g., DBV-S2) and the above-noted ETSI, Draft EN 302307, v.1.1.1, June 2004 is assumed and is not described in detail herein. Finally, like-numbers on the figures represent similar elements.

Before continuing with a description of the inventive concept, a brief review of the prior art decoding algorithm for an LDPC decoder is provided. It should be noted that the decoding algorithm for an LDPC decoder is sometimes, as known in the art, called the message passing algorithm or the belief propagation algorithm. The message passing algorithm itself seems rather simple. In particular, define a set of check nodes, Mₙ={m:H_{m,n}=1} and a set of bit nodes, Nₘ={n:H_{m,n}=1}. Let u⁽¹⁾_{m,n} be the message from check node m to bit node n during the lth iteration, let v⁽¹⁾_{m,n} be the message from the bit node n to check node m during the lth iteration, and let λ⁽¹⁾ₙ denote an estimate of the a posteriori log-likelihood ratio (LLR) of the nth bit after l iterations. If the channel observation of an LDPC code block is denoted as the vector r, the message passing algorithm is as follows. At initialization, the following is computed:

$$\begin{matrix}{λ}_{n}^{( 0 )} = log \frac{Pr ( r \vert {b}_{n} = 0 )}{Pr ( r \vert {b}_{n} = 1 )} , and & ( 1 ) \\ let {v}_{n , m}^{( 0 )} = {λ}_{n}^{( 0 )} , for all n ∈ \{ 0 , … , N - 1 ) and m ∈ {M}_{n} . & ( 2 )\end{matrix}$$

After initialization, i.e., for iterations l=1, 2, . . . , lₘₐₓ the following computations are performed for each check node update and bit node update. For each check node update:

for m ε(0, 1, . . . , M−1) and nεNₘ, compute

$${u}_{m , n}^{( l )} = ( {\prod }_{i ∈ {N}_{m} - ( n )} sign \{ {v}_{i , m}^{( l - 1 )} \} ) f ( {\sum }_{i ∈ {N}_{m} - ( n )} f ( \vert {v}_{i , m}^{( l - 1 )} \vert ) , \\ where f ( x ) = log \frac{{e}^{x} + 1}{{e}^{x} - 1} . \qquad ( 3 )$$

And, for each bit node update:

for nε{0, 1, . . . , N−1} and mεMₙ, compute

$${λ}_{n}^{( l )} = {λ}_{n}^{( 0 )} + {\sum }_{m ∈ {M}_{n}} {u}_{m , n}^{( l )} \\ {v}_{n , m}^{( l )} = {λ}_{n}^{( l )} - {u}_{m , n}^{( l )} \qquad ( 4 )$$

The hard-decision and termination criterion for the decoding algorithm are as follows:

bₙ=0 if λ⁽¹⁾ₙ>0, otherwise bₙ=1, (5)

where a check is made if the bit sequence b₀, b₁, . . . , b_{N-1} satisfies all parity check equations defined by the parity check matrix, H. If so, the iteration terminates, otherwise, let l←(l+1) and continue the iteration until the maximum number of iterations is reached.

As noted above, the message passing algorithm itself is rather simple. However, actual implementations of an LDPC decoder are not always simple due to the hardware constraints, the length of LDPC codes, and the near-random connections between bit nodes and check nodes. This is particularly illustrated by the LDPC codes used in a DVB-S2 satellite system, which will be used to illustrate the inventive concept. However, the inventive concept is not so limited and is applicable to any type of LDPC decoder whether a part of a satellite system or not.

In DVB-S2 there are four possible modulation schemes: QPSK (quadrature phase shift keying), 8-PSK, 16-APSK (amplitude phase shift keying) and 32-APSK. Before modulation, data is encoded using a serial concatenated code scheme where an LDPC code is the inner code and a BCH (Bose-Chaudhuri-Hochquenghem) code is the outer code. Except for QPSK modulation, the LDPC codeword bits are also interleaved before modulation. With respect to the coding process, the BCH code is a very weak code, which is used to correct the residual errors after the LDPC decoding process in order to achieve 10⁻⁷ packet error rates. With respect to the LDPC coding, there are two types of LDPC codes. The first type is referred to herein as a “normal LDPC code”, which has a code block length of 64800 bits. The second type is a short LDPC code, which has a code block length of 16200 bits. Since the two types of codes have similar structures, the normal LDPC code will be described herein. For convenience only, and unless stated otherwise, any subsequent references to the term “LDPC code” means a normal LDPC code. However, use of the term “LDPC code” in the claims is not so limited.

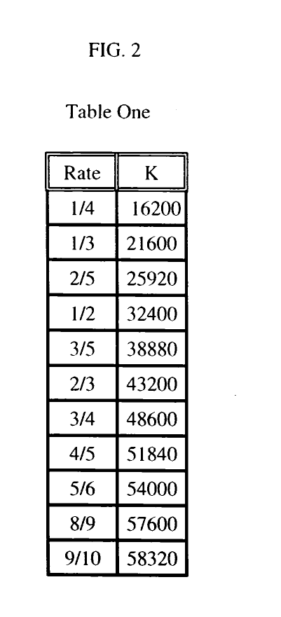

For a DVB-S2 system (e.g., see the above-noted ETSI, Draft EN 302307, v.1.1.1, June 2004), there are a number of different LDPC code rates available as shown in Table One of FIG. 2. The first column of the table, labeled “rate”, lists these different LDPC code rates. The next column, “K”, lists the amount of data encoded in an LDPC coded block at that particular LDPC code rate. In the context of the DVB-S2 system, this data includes the earlier mentioned BCH-coded data. For example, for a ¼ code rate an un-encoded data block has a size of 16008 bits (not shown in Table One). This un-encoded data block is then BCH-coded into a BCH-coded block of 16,200 bits (the respective value for K in Table One for an LDPC ¼ code rate). This BCH-coded block is then LDPC-coded at the particular code rate. Since in this example the LDPC code rate is ¼, the size of the resulting LDPC-coded block is 68,400 bits (not shown in Table One). It should be noted that the corresponding receiver determines the code rate from data contained in a predefined portion of the received DVB-S2 signal format.

As can be observed from Table One, there are 11 possible code rates, ranging from ¼ to 9/10. However, codes with different rates have different parity check matrices as defined in DVB-S2. As such, high rate code words can not be obtained by puncturing of the low rate code words. Thus, large code block length and multiple code rates make the hardware implementation of the LDPC decoder very complicated.

As noted earlier, there are three major architectures for LDPC decoder implementations. In the context of DVB-S2, the LDPC code block length is 64,800 bits, which is rather large. In addition, the DVB-S2 decoder requires low latency. Hence, a fully parallel or serial architecture is not suitable for decoder implementations and a partially parallel architecture needs to be designed. However, there is no consistent design approach to implementing an efficient partially parallel LDPC decoder.

To overcome this difficulty, and in accordance with the principles of the invention, it is possible to reduce the complexity of an LDPC decoder by exploiting certain properties of the DVB-S2 parity check matrices. For irregular LDPC codes, one desirable rule is that the distribution of the check node degree (D_{C}) be as uniform as possible. With regard to the DVB-S2 LDPC codes, it can be determined that for each associated parity check matrix each check node has the same check node degree (D_{c}) except for the first check node of the parity check matrix, which has a degree of (D_{c}−1). Thus, the LDPC codes in DVB-S2 follow the above-noted rule.

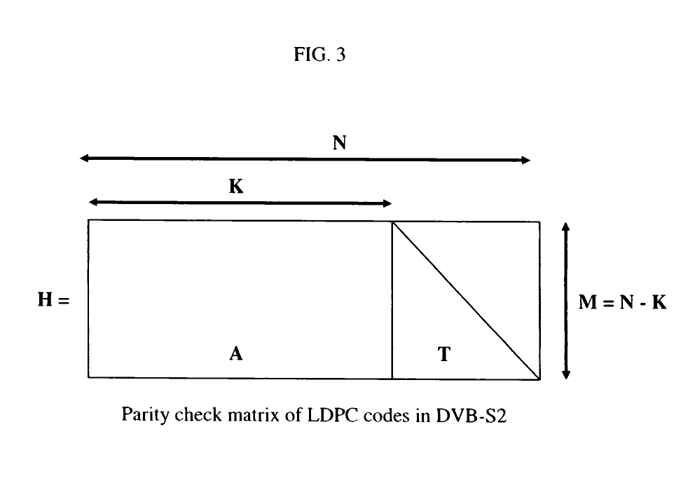

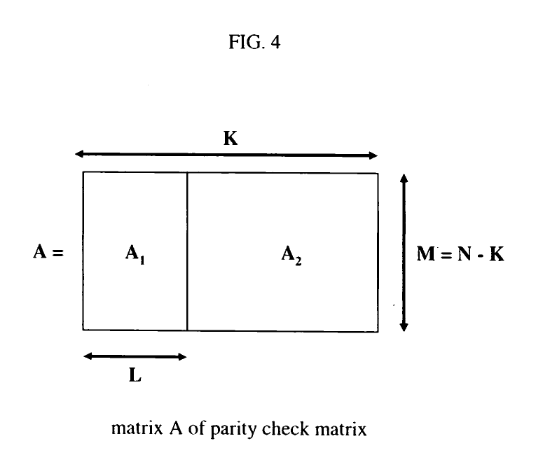

In addition, it is known that all the DVB-S2 parity check matrices are of the form [A|T], as illustrated in FIG. 3. The matrix A is a rectangular matrix of dimensions M×K, where M=N−K. Matrix A is further illustrated in FIG. 4. It should be noted that matrix A itself can be treated as a parity-check matrix, which consists of two submatrices, A₁ and A₂, where A₁ is a matrix with dimension M×L, and A₂ is a matrix with dimension M×(K−L). The bit nodes in matrix A₁ have the same degree, denoted as DV₁ and, likewise, the degree of the bit nodes in matrix A₂ are the same and fixed at DV₂=3.

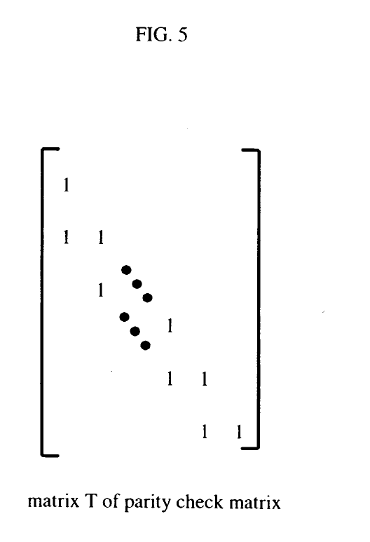

Turning now to matrix T, this matrix is a special M×M lower triangular matrix, as show in FIG. 5. This type of structure is sometimes called a staircase structure, which provides bit nodes of degree 2, i.e., DV₃=2, for a given degree distribution. Furthermore, it should be noted that this lower triangle structure enables fast LDPC encoding (e.g., see the ETSI, Draft EN 302307, v.1.1.1, June 2004).

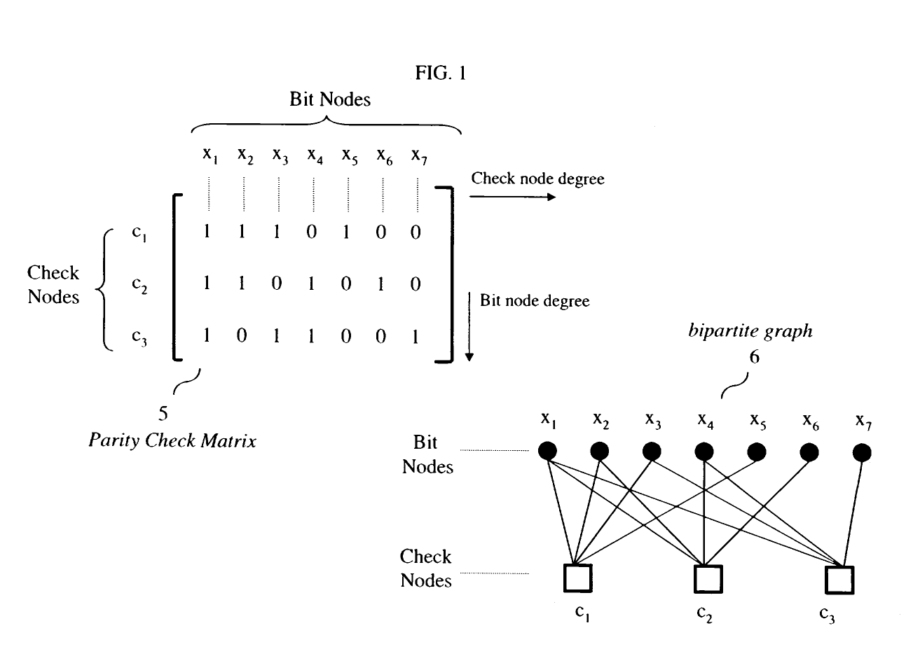

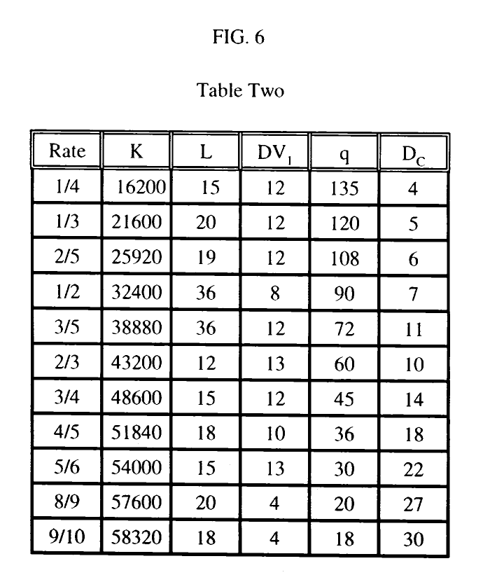

Turning now to FIG. 6, Table Two illustrates the values for the above-mentioned L, DV₁, q and D_{c} for the different DVB-S2 code rates. The first two columns of Table Two, labeled “rate” and “K” are identical to the columns shown in Table One of FIG. 1.

In accordance with the principles of the invention, further analysis of the structure of matrix A sheds additional light on implementing an LDPC decoder. In particular, for every group of 360 bit nodes {360×k, . . . , 360×k+359}, the check nodes they involve can be specified by the check nodes of the first bit node with an index (360×k). For example, if the first bit node in the group involves a set of check nodes {C₁,C₂, . . . , C_{DV}}, where DV is the degree of the bit nodes, the bit node with index (360×k+m) involves a set of check nodes, given as:

{c|c=(x+m×q)mod M,x [symbol] {C₁,C₂, . . . , C_{DV}}}, (6)

where

$$q = \frac{M}{360} .$$

In light of the above-described observations, and in accordance with the principles of the invention, the bit nodes and check nodes are each organized into multiple groups in order to carry out the bit node update or check node update operations simultaneously. With respect to this particular example, and as illustrated by equation (6), every 360 bit nodes {360×k, . . . , 360×k+359} can be processed as one group, i.e., the bit nodes are grouped consecutively, such as,
for nε{0, 1, . . . , (K/360)−1}, the n-th bit node group will contain the bit node {360n, 360n+1, . . . , 360n+358, 360n+359}.

### These bit nodes are also referred to herein as systematic-bit nodes.

With respect to the check nodes, the check nodes are re-arranged into q groups as follows (where, as noted above,

$$q = \frac{M}{360} ,$$

i.e., q varies as a function of the code rate):
Group 0: (0,q,2×q,3×q, . . . , 359×q);
Group 1: (1,l+q,l+2×q,1+3×q, . . . , 1+359×q);
Group q−2: {q−2,q−2+q, . . . , q−2+359×q}; and
Group q−1: {q−1,q−1+q, . . . , q−1+359×q}.

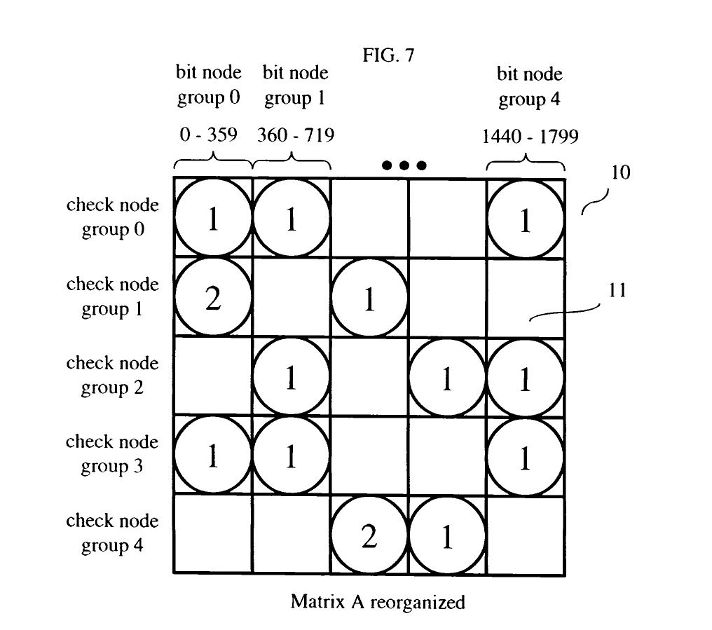

Since an LDPC-coded block has a size of N=64,800 bits, a smaller size A matrix will be described below to further illustrate the inventive concept. FIG. 7 shows a matrix 10 (a matrix of form A) re-organized in accordance with the principles of the invention. The matrix 10 is for an LDPC code having the following parameters:

N=10×360=3600;

M=5×360=1800;

q=5;

DV₁=4; and

L=360.

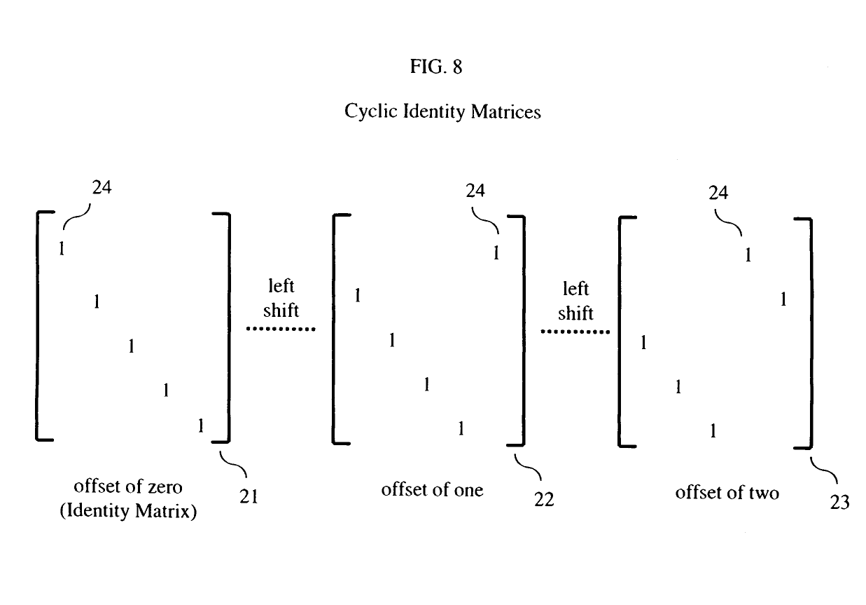

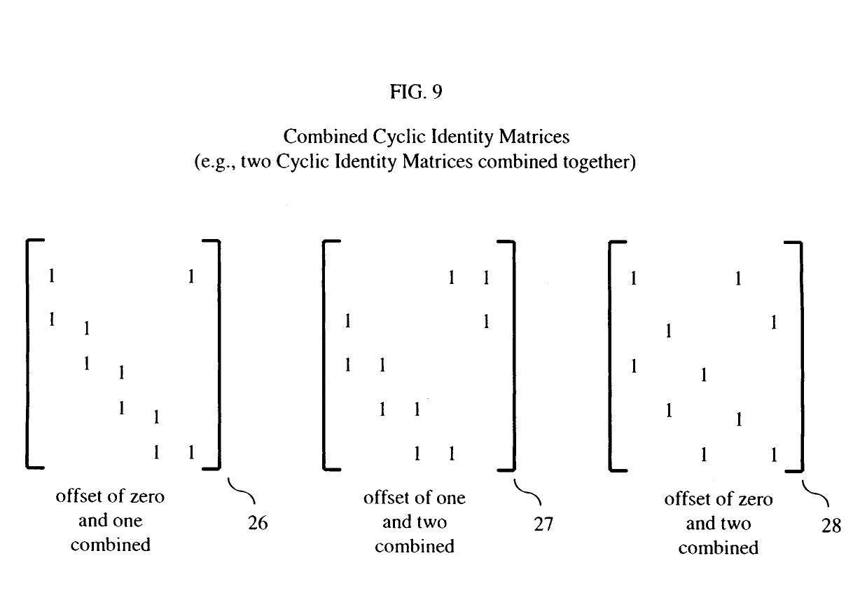

Each square, 11, represents a submatrix of dimensions 360×360. Other than the inventive concept, it should be noted that the notation shown in FIG. 7 is known in the art with respect to similar code constructions (e.g., see David J. C. Mackay, Simon T. Wilson and Matthew C. Davey, “Comparison of Constructions of Irregular Gallager Codes”, IEEE Transactions on Communications, Vol. 47, pp. 1449-1454, October 1999; and D. Sridhara, T. Fuja and R. M. Tanner, “Low density parity check codes from permutation matrices,” Conf. On Info. Sciences and Sys., The John Hopkins University, March 2001). In particular, a blank square represents an all-zero matrix and an integer in a circle within a square represents a number of cyclic identity matrices superposed on the surrounding square. The number one represents a single cyclic identity matrix having a particular offset while the number two represents a combination of two cyclic identity matrices. This is further illustrated in FIGS. 8 and 9. Turning first to FIG. 8, this figure illustrates different offsets of in the context of a left-shifted cyclic identity matrix. Matrix 21 illustrates the identity matrix. This is also referred to herein as a cyclic identity matrix with no shift, i.e., having an offset of zero. Moving from left to right in FIG. 8, matrix 21 is left-shifted once resulting in matrix 22. If one compares the position of element 24 in matrix 22 with its previous position in matrix 21, it can be observed that element 24 appears in the same row, but has been shifted one column to the left (with the columns, in effect, wrapping around). As such, matrix 22 is a cyclic identity matrix having an offset of one. Matrix 22 is again left-shifted once resulting now in matrix 23. Again, it can be observed from FIG. 8 that element 24 has shifted one column to the left from its previous position in matrix 22. Since matrix 23 is the result of two left shifts, matrix 23 is a cyclic identity matrix having an offset of two. Other offsets can be derived in a similar fashion and, although not shown in FIG. 8, right-shifting operations could also be equivalently performed in the other direction. For convenience, a left-shifted cyclic identity matrix is denoted herein as the matrix I^{(y)}, where the value of the superscript represents the value of the offset.

Referring now to FIG. 9, the concept of a combined cyclic identity matrix is illustrated. A combined cyclic identity matrix is a combination of two or more cyclic identity matrices. With respect to FIG. 9, this figure illustrates combinations of two cyclic identity matrices. In particular, matrix 26 is a combination of matrices 21 and 22 of FIG. 8, matrix 27 is a combination of matrices 22 and 23 of FIG. 8, and matrix 28 is a combination of matrices 21 and 23 of FIG. 8. Other combinations can be derived in a similar fashion.

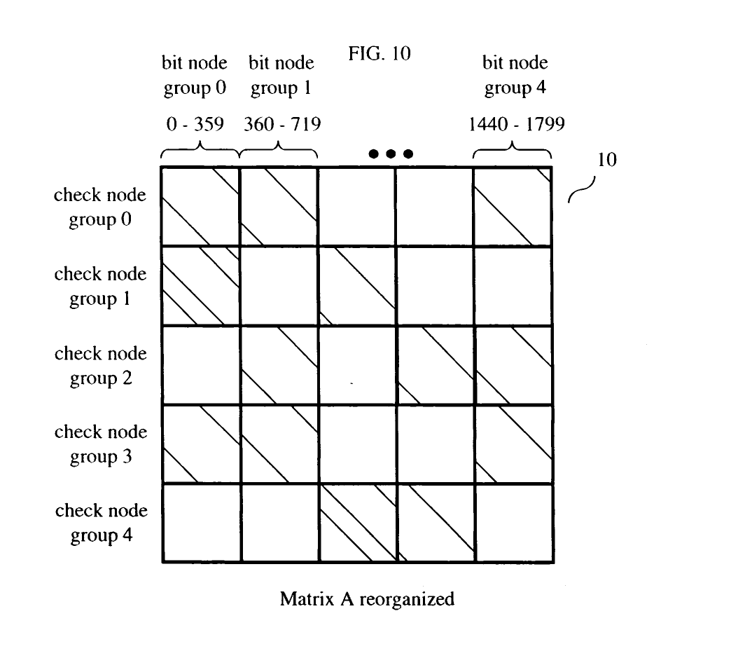

In light of the above, FIG. 10 again illustrates matrix 10 of FIG. 7 (a matrix of form A) with the patterns of the particular left-shifted cyclic identity matrices and combined cyclic identity matrices shown. If there are lines within a submatrix, this represents that the corresponding submatrix elements on which the line crosses have a value of “1” and the other submatrix elements have values of “0”. For a submatrix having no lines inside it, this represent an all zero submatrix.

As a result, it can be observed from FIGS. 7 and 10 that for all LDPC codes, the A matrix of the parity check matrix comprises three types of sub-matrices of dimension 360×360:
a zero matrix;
a cyclic identify matrix, I^{(y)}, for 0≦y≦359; and
a combined cyclic identity matrix, I^{(x)}+I^{(y)}, for x≠y, and 0≦x, y≦359.

Now, there is another way to describe an LDPC parity check matrix. In particular, let H(m,n) denote the submatrix of the A matrix of the parity check matrix corresponding to check node group m, and bit node group n, and only show the nonzero submatrices. For the n-th row in the address of the Parity Bit Accumulators Table (other than the inventive concept, addresses of parity bit accumulators are described in ETSI, Draft EN 302307, v.1.1.1, June 2004), a set of submatrices is obtained corresponding to the n-th bit node group. For a given number x in the n-th row of the table, the corresponding check node group is m=x mod q, the value for the left cyclic shift number is y=└x/q┘, and the corresponding submatrix is H(m,n)=I^{(y)}. For example, from FIG. 6, for a rate ½ code, the value of q=90, and from Annex B of the ETSI, Draft EN 302307, v.1.1.1, June 2004, the zero-th row (n=0) of the address of the Parity Bit Accumulators Table is:

54, 9318, 14392, 27561, 26909, 10219, 2534, 8597.

### (In terms of the nomenclature in the ETSI draft, the zero-th row of the parity bit accumulator table for a rate ½ code corresponds to the rows of the parity matrix for the zero-th bit node for which there is a “1” in the column.)

Hence the corresponding submatrices for the A matrix are:

54: H(54,0)=I⁽⁰⁾;

9318: H(48,0)=I⁽¹⁰³⁾;

14392: H(82,0)=I⁽¹⁵⁹⁾;

27561: H(21,0)=I⁽³⁰⁶⁾;

26909: H(89,0)=I⁽²⁹⁸⁾;

10219: H(49,0)=I⁽¹¹³⁾;

2534: H(14,0)=I⁽²⁸⁾; and

9597: H(47,0)=I⁽⁹⁵⁾.

Likewise, consider the first row (n=1) from the same Parity Bit Accumulators Table (again, from Annex B of the ETSI, Draft EN 302307, v.1.1.1, June 2004):

55, 7263, 4635, 2530, 28130, 3033, 23830, 3651.

Hence the corresponding submatrices for the A matrix are:

55: H(55,1)=I⁽⁰⁾;

3033, 7263: H(63,1)=I⁽³³⁾+I⁽⁸⁰⁾;

4635: H(45,1)=I⁽⁵¹⁾;

2530: H(10,1)=I⁽²⁸⁾;

28130: H(50,1)=I⁽³¹²⁾;

23830: H(70,1)=I⁽²⁶⁴⁾; and

3651: H(51,1)=I⁽⁴⁰⁾.

It should be noted that the calculations for 3033 and 7263 with respect to the first row both result in the same submatrix H^{(63,1)} but with different cyclic identity matrices, I⁽³³⁾ and I⁽⁸⁰⁾, respectively. Hence, the submatrix H(63,1) is the summation of these two cyclic identity matrices as shown above.

As noted earlier, all DVB-S2 parity check matrices are of the form [A|T]. In accordance with the principles of the invention, in matrix T the bit nodes are grouped in a different way, compared with the bit nodes in matrix A. For nε{(K/360), . . . , (N/360)−1}, the n-th bit node group contains the bit node:

K+(n−K/360)+{0,q,2×q,3×q, . . . , 359×q).

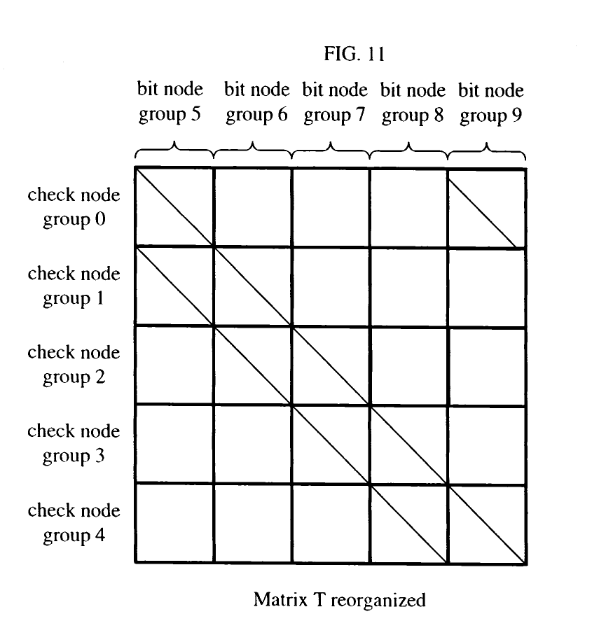

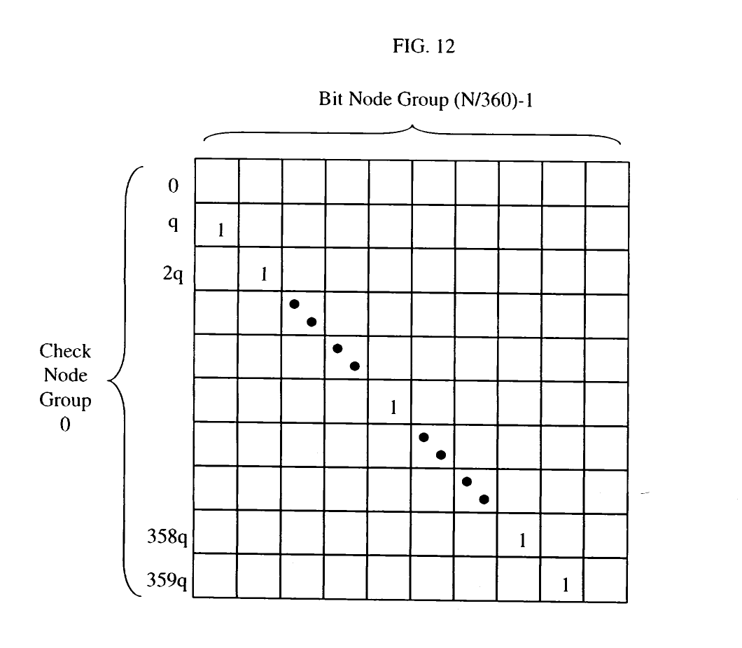

The discontinuity of the parity-bit nodes in one bit node group is due to the re-order of the parity-check equations. An example of the resulting T matrix is shown in FIG. 11. It can be observed from FIG. 11 that there are three possible squares of dimension 360×360 in matrix T:
a zero matrix;
a identity matrix, I⁽⁰⁾; and
a square H(0,(N/360)−1) that contains a special submatrix of dimension 360×360, shown in FIG. 12.

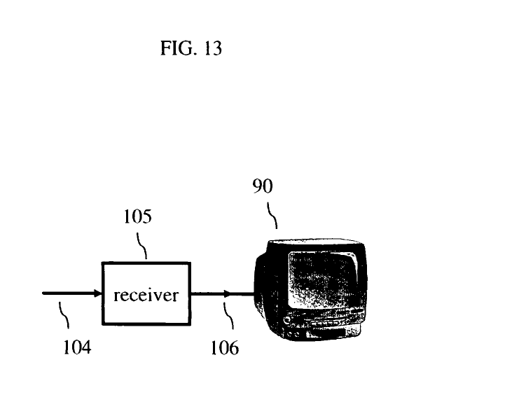

The above-described rearrangement of the parity check matrix is now used to implement an LDPC decoder in accordance with the principles of the invention. An illustrative portion of a communications system in accordance with the principles of the invention is shown in FIG. 13. As can be observed from FIG. 13, a signal 104 is received by a receiver 105. Signal 104 conveys information representative of control signaling, content (e.g., video), etc. In the context of this example, it is assumed that signal 104 represents a DVB-S2 downlink satellite signal after reception by an antenna (not shown). Receiver 105 processes signal 104 in accordance with the principles of the invention (described below) and provides a signal 106 for conveying particular content to a multi-media endpoint as represented by television (TV) 90 for display thereon.

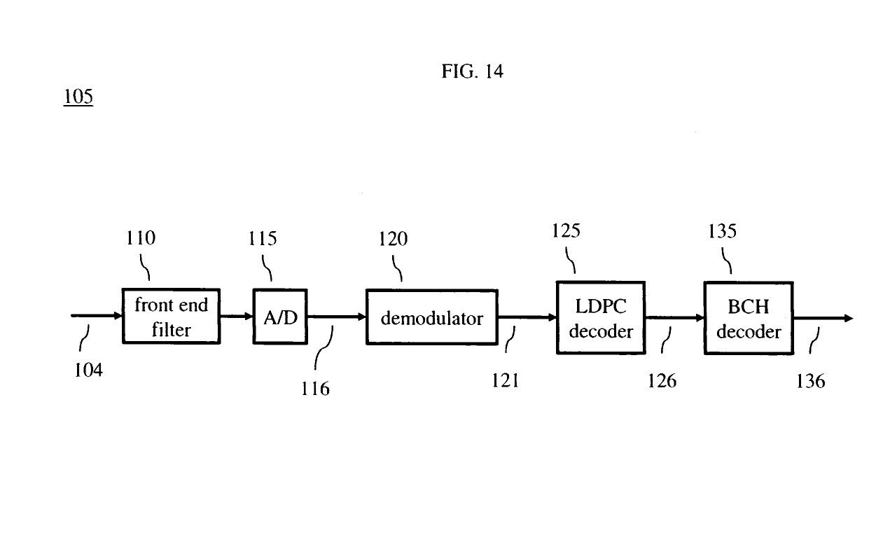

Turning now to FIG. 14, an illustrative portion of receiver 105 in accordance with the principles of the invention is shown. Receiver 105 includes front end filter 110, analog-to-digital (A/D) converter 115, demodulator 120, LDPC decoder 125 and BCH decoder 135. Front end filter 110 down-converts (e.g., from the satellite transmission bands) and filters received signal 104 to provide a near baseband signal to A/D converter 115, which samples the down converted signal to convert the signal to the digital domain and provide signal 116, which is a sequence of samples, to demodulator 120. The latter performs demodulation of signal 116 (including carrier recovery) and provides a demodulated signal 121 to LDPC decoder 125, which, in accordance with the principles of the invention, decodes the demodulated signal point stream 121 to provide signal 126, which represents a BCH-coded signal, or data stream. Signal 126 is applied to BCH decoder 135 for recovery of the transmitted data as represented by signal 136. At least some of the data from signal 136 is eventually provided (not shown in FIG. 14) to TV 90 via signal 106. (In this regard, receiver 105 may additionally process the data before application to TV 90 and/or directly provide the data to TV 90.)

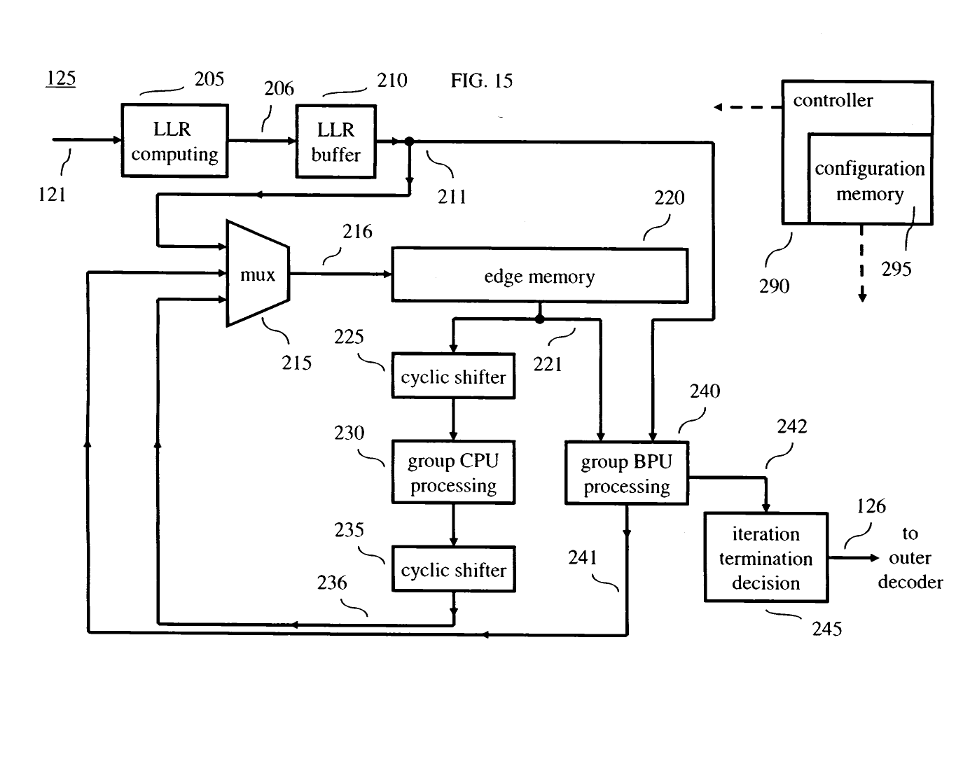

In accordance with the principles of the invention, an illustrative embodiment of LDPC decoder 125 is shown in FIG. 15. LDPC decoder 125 comprises log-likelihood ratio (LLR) computing element 205, LLR buffer 210, multiplexer (mux) 215, edge memory 220, cyclic shifters 225 and 235, a plurality of check node processing units (group CPU processing) 230, a plurality of bit node processing units (group BPU processing) 240, iteration termination decision element 245 and controller 290. The latter is representative of a stored-program controlled processor (e.g., a microprocessor and associated memory) or a state machine, etc.

LLR computing element 205 receives the demodulated signal point stream signal 121 and computes the LLR as known in the art to provide signal 206, which represents the calculated LLR values that are representative of the received LDPC coded blocks. In particular, LLR computing element 205 computes the LLR of codeword bits as

$${λ}_{n}^{( 0 )} = log \frac{Pr ( r \vert {b}_{n} = 0 )}{Pr ( r \vert {b}_{n} = 1 )}$$

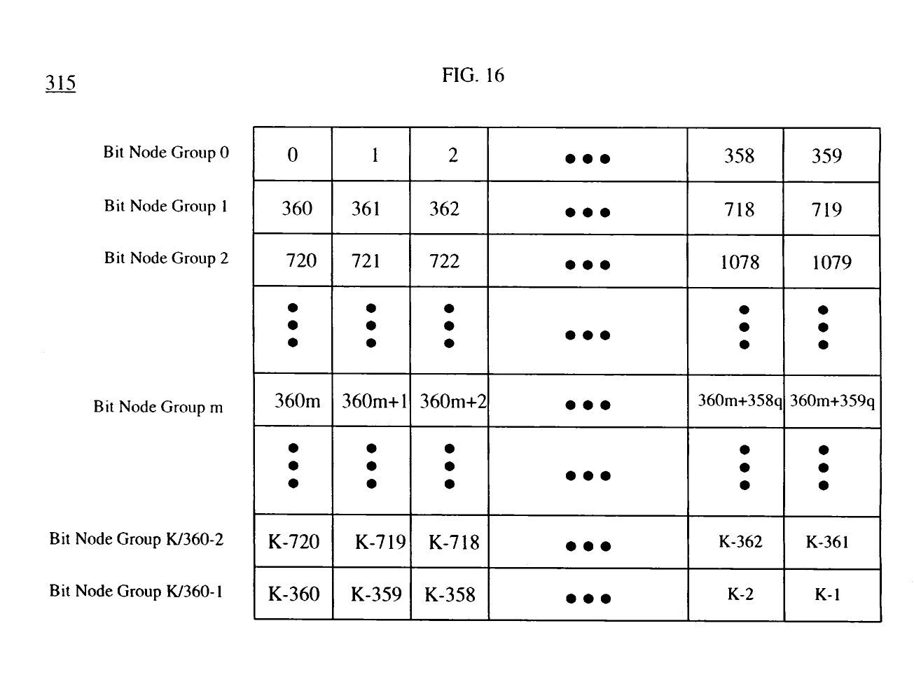

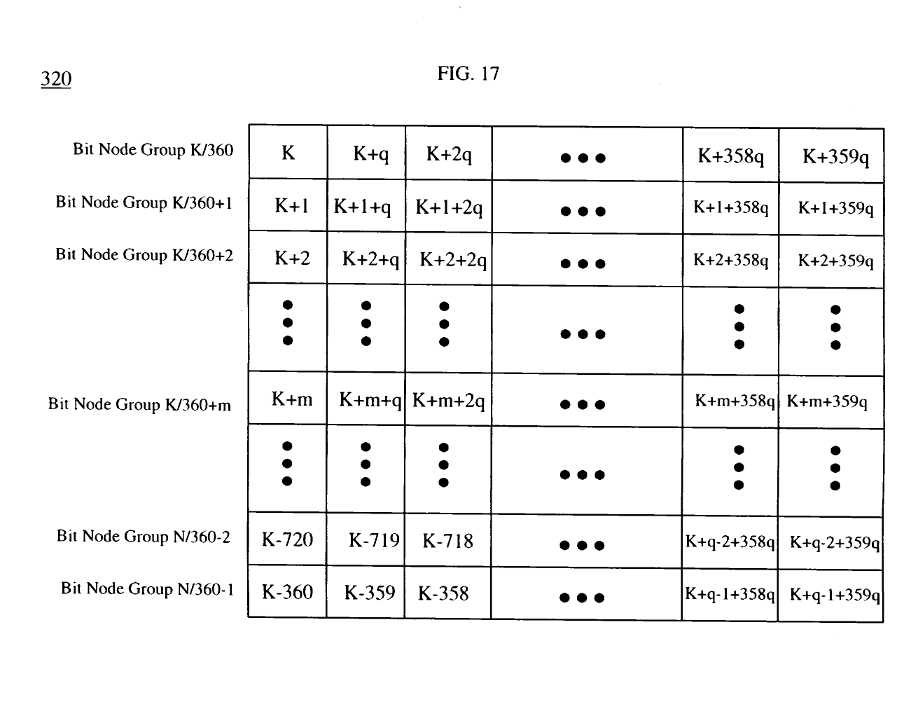

based on the modulation scheme and the signal to noise ratio of the received signal. For simplicity, lookup tables (not shown) are used to implement this function. In addition, LLR computing element 205 also de-interleaves the LLR values before they are sent, via signal 206, to LLR buffer 210 (as noted earlier, the LDPC coded bit stream was interleaved before modulation unless QPSK modulation was used). LLR buffer 210 is a storage element and comprises, e.g., a double buffer structure to alternately store the data representative of the received LDPC coded blocks. As such, when one buffer is being filled, data from the other buffer is processed, via signal 211, for decoding of the previously received LDPC coded block. An illustrative memory structure 315 for use in an LLR buffer for the systematic bit nodes of matrix A is shown in FIG. 16; while an illustrative memory structure 320 for use in the LLR buffer for the bit nodes of matrix T is shown in FIG. 17. From FIGS. 16 and 17, the number of memory words required is N/360=64800/360=180, where the bit width of one memory word is 360×6=2160 bits if it is assumed that 6 bits are required to store the initial channel information (λ⁽⁰⁾ₙ). As such, LLR buffer 210 provides LDPC coded blocks via signal 211 to mux 215. The latter is controlled by a processor as represented by controller 290 which controls the various elements of LDPC decoder 125 as represented for simplicity by the dashed arrows. Mux 215 provides, via signal 216, either of three types of data to edge memory 220: a received LDPC coded block for decoding (via signal 211); bit node processing data (via signal 241), or check node processing data (via signal 236).

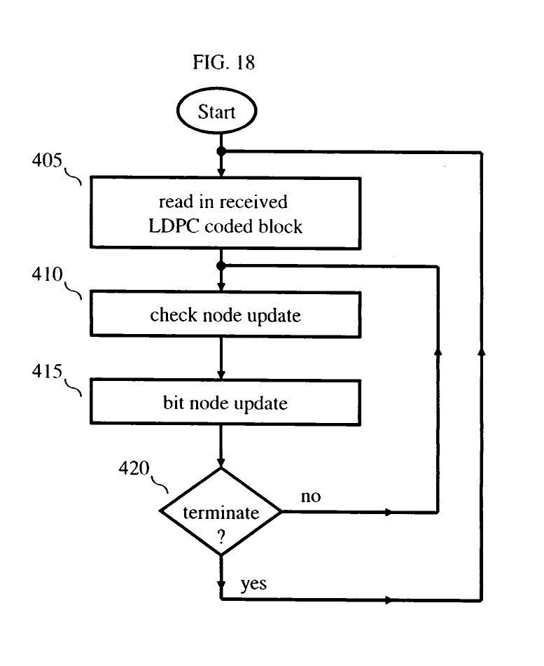

Reference now should be made to FIG. 18, which shows an illustrative flow chart of an overall process that is used in LDPC decoder 125 for performing LDPC decoding. In step 405, an LDPC coded block is provided from LLR buffer 210 to edge memory 220 for storage therein. In steps 410 and 415, LDPC decoding is performed. In particular, check node updates (step 410) and bit node updates (step 415) operate on the data stored in edge memory 220 (described below). In step 420, a check is made if the decoding process should be terminated, e.g., from equation (5), above. If the process is terminated, execution returns to step 405 to begin decoding the next LDPC coded block, otherwise, decoding continues with another round of check node and bit node updates via steps 410 and 415. It should be noted that for simplicity error conditions are not shown in the flow chart of FIG. 18.

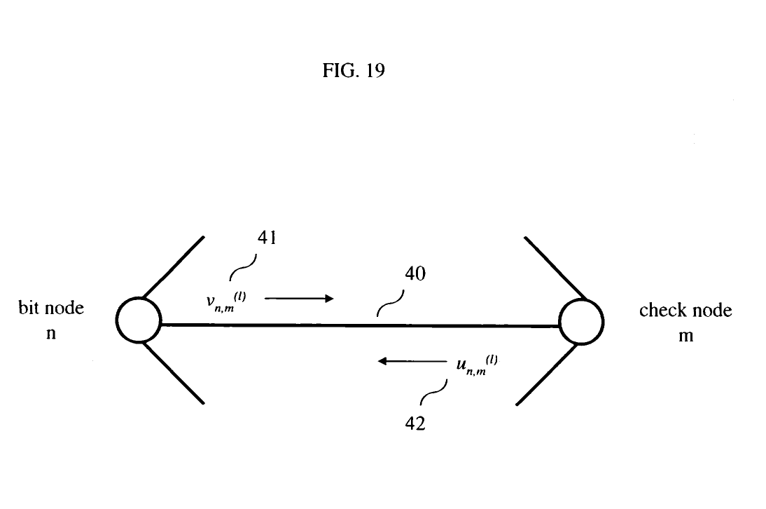

As noted above, edge memory 220 stores the LDPC coded data and is accessed in both the check node update and bit node update steps shown in FIG. 18. Edge memory 220 is representative of a storage element. While edge memory 220 can be implemented using registers, which allow for fast access (albeit with higher design complexity), preferably a bank of memory is a more suitable implementation given the length of the LDPC coded blocks. In the LDPC decoding process, messages are passing through the edges of the bipartite graph between bit nodes and check nodes. This is conceptually illustrated in FIG. 19, which shows a portion of an illustrative bipartite graph. For example, a bit node n is coupled to a check node m by an edge 40, which enables the passing of messages therebetween as represented by bit node message 41 and check node message 42. Since the memory used in the LDPC decoding process is associated with the edges between the check nodes and the bit nodes, this memory is referred to herein as edge memory. As such, edge memory 220 stores the messages from check nodes to bit nodes {u^{(l)}_{m,n}}, via signal 236, or the messages from bit nodes to check nodes {v^{(l))hd n,m}}, via signal 241. In particular, and as can be observed from the flow chart of FIG. 18, LDPC decoder 125 has at least two phases: a check node update phase (e.g., step 410 of FIG. 18) and a bit node update phase (e.g., step 415 of FIG. 18). At the beginning of the check-node update phase, {v^{(l-1)}_{n,m}} is stored in a memory location of edge memory 220; while at the end of the check-node update phase, {u^{(l)}_{m,n}} is computed and stored in the same memory location. Likewise, in the bit node update phase, {u^{(l)}_{m,n}} is read out and {v^{(l)}_{n,m}} is computed and stored into the same memory location. Thus, in a partially parallel architecture, the same memory location is used to store {v^{(l)}_{n,m}} or {u^{(l)}_{m,n}} depending on the phase of the LDPC decoder.

In accordance with the principles of the invention, edge memory 220 can be organized in terms of the bits nodes or in terms of the check nodes in accordance with the above-described reorganization of the parity matrix. It should be noted that the overall amount of memory required is the same for both cases since the number of edges is fixed for a particular parity check matrix.

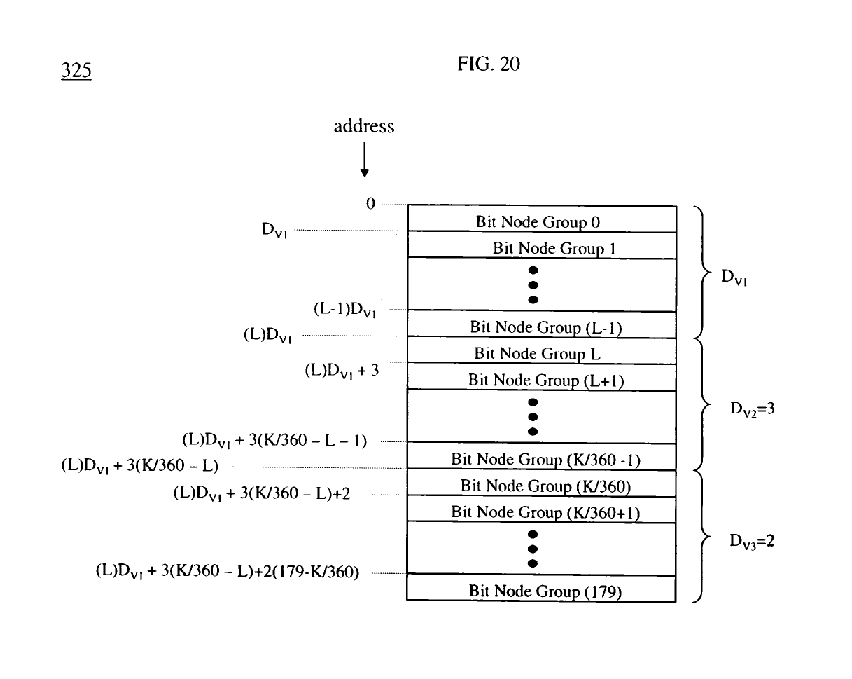

In one embodiment, edge memory 220 is illustratively organized in terms of bit nodes. In this case, one memory word is used to store all the messages corresponding to a circularly shifted identity matrix (described above). The memory words associated with a bit node group are stored in consecutive address locations, which makes the bit node update simple. An illustrative memory structure 325 for use in edge memory 220 is shown in FIG. 20. Since the memory of edge memory 220 is organized in terms of bit nodes, this memory may also be referred to as a bit node memory bank.

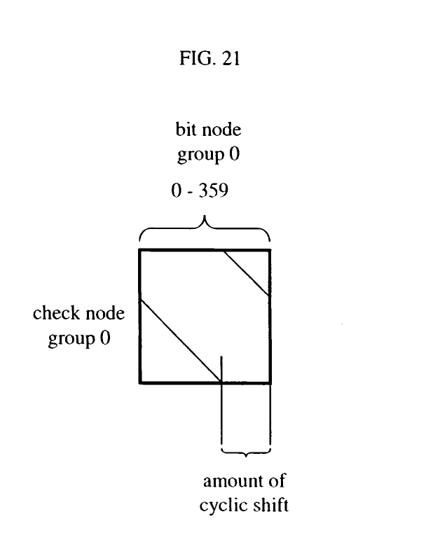

Returning back to FIG. 15, data stored in edge memory 220 is provided to either a bit node processing path or a check node processing path via signal 221. With respect to the check node processing path, this path is active in the check node update phase (step 410 of FIG. 18). In particular, data (whether the initial LDPC coded data or the subsequent message data, {v^{(l-1)}_{n,m}} is provided to group CPU processing 230 via cyclic shifter 225. Since edge memory 220 is organized in terms of bit nodes, cyclic shifter 225 cyclically shifts the data in the memory words such that the data for one check node group are aligned. This is illustrated in FIG. 21, which shows the amount of cyclic shift for check node group 0/bit node group 0. Group CPU processing 230 comprises 360 check node processing units (described further below) for computing {u^{(l)}_{m,n}} and for providing {u^{(l)}_{m,n}} to cyclic shifter 235, which again reorients the data in the memory words such that the data for one bit node group are aligned. Cyclic shifter 235 provides {u^{(l)}_{m,n}}, via signal 236, to edge memory 220 via mux 215 and signal 216. It should be noted that one cyclic shifter may be used instead of two by multiplexing its operation in the time domain. Turning now to the bit node processing path, this path is active in the bit node update phase (step 415 of FIG. 18). In particular, data, {u^{(l)}_{m,n}} is provided to group BPU processing 240 Group BPU processing 240 illustratively comprises 360 bit node processing units (described further below) for computing {v^{(l)}_{n,m}} and for providing {v^{(l)}_{n,m}}, via signal 241, to edge memory 220 via mux 215 and signal 216.

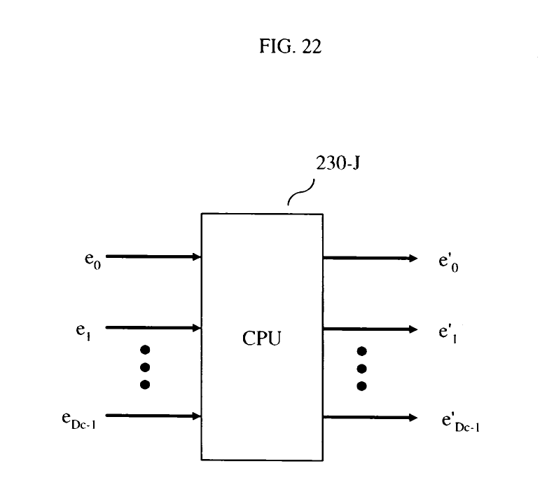

As described above, group CPU processing 230 comprises 360 check node processing units. An illustrative check node processing unit (CPU) 230-J, where 0<J≦360, is shown in FIG. 22. CPU 230-J processes a set of input messages {e₀, e₁, . . . , e_{D}_{_{C}}₋₁} to provide a corresponding set of output messages {e′₀, e′₁, . . . , e′_{D}_{_{C}}₋₁}. As noted earlier, equation (3) is used in LDPC decoding for generating the set of output messages. However, the complexity of each check node processing unit increases if the exact formula in equation (3) is implemented. Indeed, since the maximum possible check node degree is 30, the implementation of the adder array and all the functions ƒ(•) become very complicated even though the function ƒ(•) can be implemented by a simple look-up table. In order to reduce the complexity of a check node processing unit, the CPU 230-J implements the following approach. In particular, assume that {e₀, e₁, . . . , e_{D}_{_{C}}₋₁} are the set of input messages to a check node processing unit (CPU). Then, compute

$$\begin{matrix}{s}_{k} = sign ( {e}_{k} ) ; & ( 7 ) \\ S = {\prod }_{k = 0}^{{D}_{c} - 1} {s}_{k} , & ( 8 )\end{matrix}$$

Now, select the 3 smallest values in the set |e₀|,|e_{1|}, . . . , |e_{D}_{_{C}}₋₁| and let their corresponding indices be m₀, m₁, m₂. After this, the following four values are computed:

λ₀=g(|eₘ_{₁}|,|eₘ_{₂}|), (9)

λ₁=g(|eₘ_{₀}|,|eₘ_{₂}|), (10)

λ₂=g(|eₘ_{₀}|,|eₘ_{₁}|), (11)

λ₃=g(g(|eₘ_{₀}|,|eₘ_{₁}|),|eₘ_{₂}|), (12)

where

g(x, y)≅sign(x)sign(y){min(|x|,|y|)−h(∥x|−|y∥)}, and (13)

h(x)=ln(1+e^{-x}). (14)

Then, a set of output messages {e′₀, e′₁, . . . , e′_{D}_{_{C}}₋₁} are computed as follows:

$${e}_{k}^{′} = {s}_{k} \times S \times \{ \begin{matrix}{λ}_{0} , for k = {m}_{0} \\ {λ}_{1} , for k = {m}_{1} \\ {λ}_{2} , for k = {m}_{2} \\ {λ}_{3} , for k \neq {m}_{0} , {m}_{1} , {m}_{2}\end{matrix} , \qquad ( 15 )$$

where 0<k≦D_{C}−1. In the above-described approach, only the three smallest values of the input messages are used to compute the output messages of the CPU. Simulations have shown that the performance loss due to this approximation is negligible for all the LDPC codes in DVB-S2.

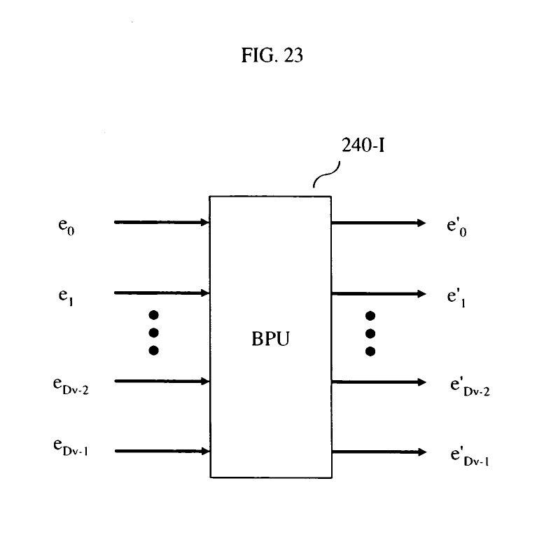

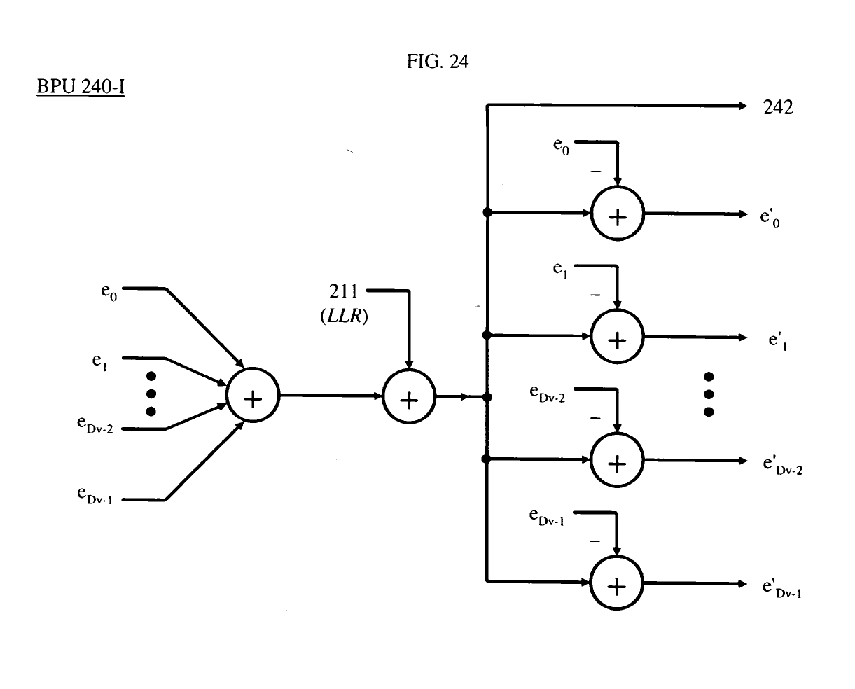

Turning now to the bit node processing, group BPU processing 240 comprises 360 bit node processing units. An illustrative bit node processing unit (BPU) 240-I, where 0<I≦360, is shown in FIG. 23. BPU 240-1 processes a set of input messages {e₀, e₁, . . . , e_{DV-1}} to provide a corresponding set of output messages {e′₀, e′₁, . . . , e′_{DV-1}}. The bit node processing operation is rather simple and is further illustrated in FIG. 24. In FIG. 24, the term LLR denotes the log-likelihood ratio of the associated bit node which is provided via signal 211 from LLR buffer 210.

The final element of LDPC decoder 125 is iteration termination decision element 245 which implements the above-described step 420 of FIG. 18. As can be observed from FIGS. 15 and 23, signal 242 is provided from the bit node processing path to iteration termination decision element 245 for use therein. If the LDPC decoding is terminated, the resulting LDPC decoded data is provided via signal 126 to BCH decoder 135, described above. Iteration termination decision element 245 provides signaling (not shown) to controller 290 with respect to continuing the LDPC decoding process or starting anew, e.g., for the next LDPC coded block.

As noted earlier, DVB-S2 supports a number of code rates with predefined parity matrices and the receiver determines the code rate from data contained in a predefined portion of the received DVB-S2 signal format. In this context, controller 290 uses the determined modulation type to select different look-up tables (not shown) for the earlier-described LLR computations and different interleaving schemes (as defined in DVB-S2). Controller 290 also configures LDPC decoder 125 in accordance with the principles of the invention to process received LDPC coded signals at the different code rates in accordance with parity matrices reorganized in accordance with the principles described earlier. For example, the above noted sub-matrix calculations (H(m, n)) can be stored a priori in a memory (e.g., configuration memory 295 of FIG. 15) for subsequent use in processing the received LDPC coded data for the different parameters as illustrated in Table Two of FIG. 6.

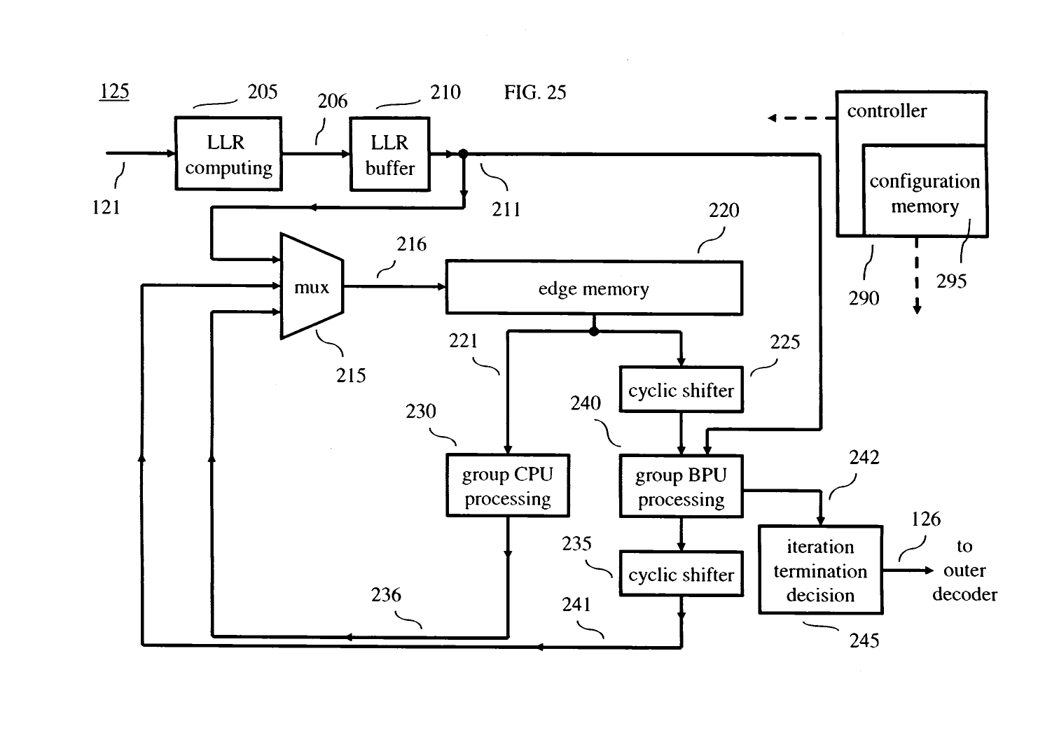

Another illustrative embodiment of LDPC decoder 125 is shown in FIG. 25. This arrangement is similar to that shown in FIG. 15 and functions in a similar fashion (e.g., see FIGS. 18, 22, 23 and 24) except that edge memory 220 is organized in terms of check nodes (and can also be referred to as a check node memory bank). As such, the two cyclic shifters 225 and 235 are now positioned before and after group BPU processing 240. Again, it should be noted that once cyclic shifter may be used instead of two by simply multiplexing its operation in the time domain.

In terms of organizing edge memory 220 in terms of check nodes, the check node memory corresponding to one check node group is put together and uses one memory location, e.g., a word, to store all the messages corresponding to a particular cyclic identity matrix. In other words, one memory word stores all the messages sent through the edges associated with a particular cyclic identity matrix. As observed earlier, and shown in Table Two of FIG. 6, for LDPC codes the degree of all check nodes, D_{C}, is the same except for the 0-th check node, which has the check node degree (D_{C}−1). As an illustration, consider the following example using a ½ rate LDPC code where, from Table Two of FIG. 6, D_{C}=7, and the 63-rd check node group corresponds to the following square matrix, which are submatrices in the parity-check matrix (calculated as illustrated earlier):

H(63,1)=I⁽³³⁾+I⁽⁸⁰⁾;

H(63,9)=I⁽⁰⁾;

H(63,29)=I⁽³²⁴⁾;

H(63,34)=I⁽¹³²⁾;

H(63,62)=I⁽⁰⁾; and

H(63,63)=I⁽⁰⁾.

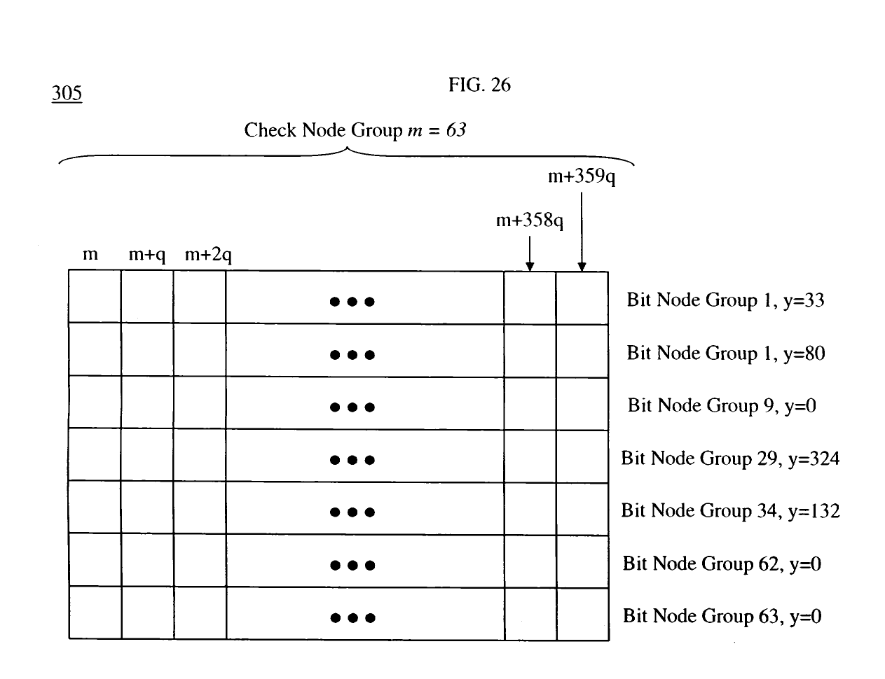

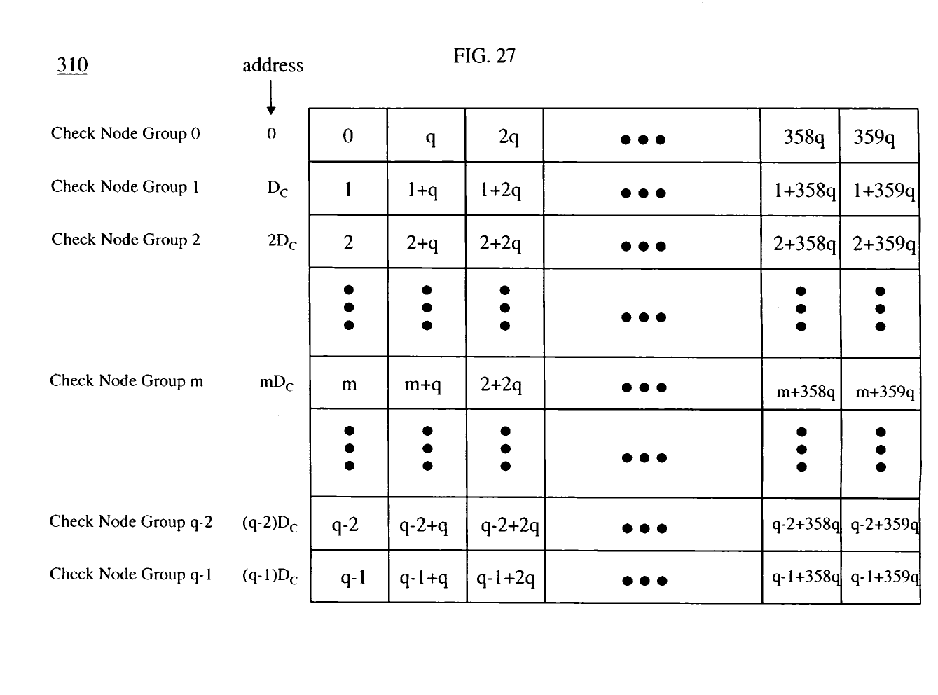

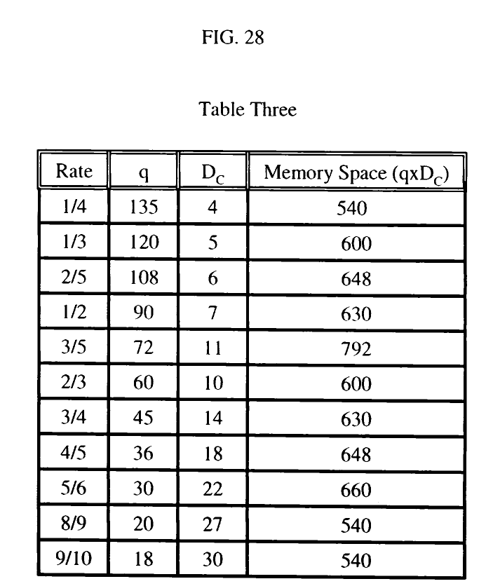

An illustrative memory bank 305 within edge memory 220 corresponding to the 63-rd check node group is shown in FIG. 26. If each row of memory bank 305 is treated as a single memory word, then only D_{C}=7 memory words are required as shown for a check node group. Indeed, all the memory banks for all the check nodes can then be put together and addressed in a linear fashion. This illustrative memory structure 310 for edge memory 220 is shown in FIG. 27. The address space of edge memory 220 for memory structure 310 is (0, 1, 2, . . . , qD_{C}−1}. In other words, the size of the address space is (q×D_{C}). The required memory space for the different LDPC code rates is shown in Table Three of FIG. 28. As can be observed from Table Three, the maximum number of memory words required is 792. If it is again assumed that each bit node message or check node message is six bits wide, than the bit width of a memory word is 360×6=2160 bits.

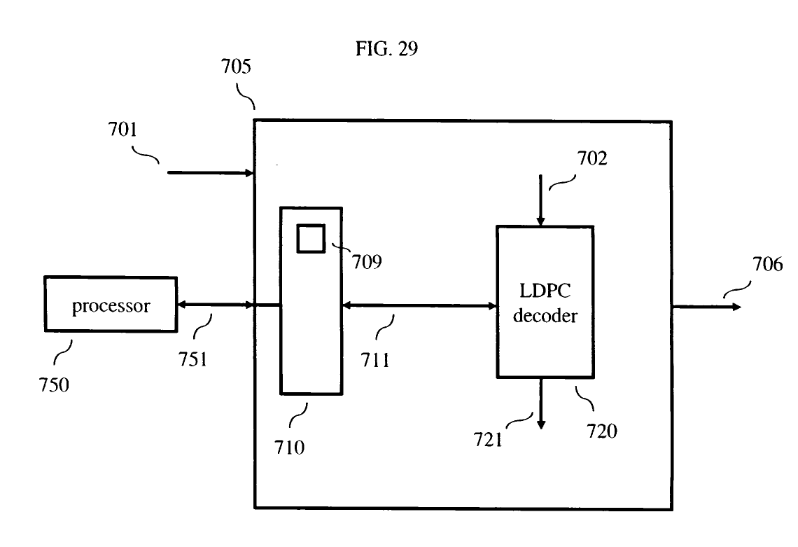

Another illustrative embodiment of the inventive concept is shown in FIG. 29. In this illustrative embodiment an integrated circuit (IC) 705 for use in a receiver (not shown) includes an LDPC decoder 720 and at least one register 710, which is coupled to bus 751. Illustratively, IC 705 is an integrated demodulator/decoder. However, only those portions of IC 705 relevant to the inventive concept are shown. For example, analog-digital converters, filters, decoders, etc., are not shown for simplicity. Bus 751 provides communication to, and from, other components of the receiver as represented by processor 750. Register 710 is representative of one, or more, registers, of IC 705, where each register comprises one, or more, bits as represented by bit 709 for controlling the operation of IC 705. The registers, or portions thereof, of IC 705 may be read-only, write-only or read/write. LDPC decoder 720 is coupled to register 710 via internal bus 711, which is representative of other signal paths and/or components of IC 705 for interfacing LDPC decoder 720 to register 710 as known in the art. In accordance with the principles of the invention, LDPC decoder 720 includes the above-described group CPUs and group BPUs. In the context of FIG. 14, IC 705 receives an IF signal 701 (e.g., signal 116 of FIG. 14) for processing via an input pin, or lead, of IC 705. A derivative of this signal, 702, is applied to LDPC decoder 720 for LDPC decoding in accordance with the principles of the invention as described above (e.g., FIGS. 15 and 24). LDPC decoder 720 provides signal 721, which is an LDPC decoded bit stream. IC 705 provides one, or more, recovered signals, as represented by signal 706. For example signal 706 is representative of signal 136 from a BCH decoder (not shown) of IC 705. In another variation of IC 705, signal 706 is representative of signal 106 of FIG. 13.

As described above, and in accordance with the principles of the invention, an LDPC decoder is described and shown that is capable of handling a variety of different code rates. Also, it should be noted that the above-described circularly shifted identity matrix could be equivalently generalized to a permutation matrix. In this case, the above-described cyclic shifter is replaced with a permutation network.

In view of the above, it should be noted that although described in the context of a satellite communications system, the inventive concept is not so limited. For example, the elements of FIG. 13 may represent other types of systems and other forms of multi-media endpoints. For example, satellite radio, terrestrial broadcast, cable TV, etc. Also, although described herein in the context of a single demodulator, it should be realized that the inventive concept is applicable to multi-modulation receivers, where information may be conveyed on different signal layers. For example, layered modulation receivers, hierarchical modulation receivers, or combinations thereof. Indeed, the invention is applicable to any type of receiver in which LDPC decoding is performed. As such, the inventive concept is not limited to the decoding of DVB-S2 LDPC codes.

As such, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements may be embodied on one or more integrated circuits (ICs). Similarly, although shown as separate elements, any or all of the elements may be implemented in a stored-program-controlled processor, e.g., a digital signal processor (DSP) or microprocessor that executes associated software, e.g., corresponding to one or more of the elements shown in FIGS. 14, 15 and/or 24, etc. Further, although shown as separate elements, the elements therein may be distributed in different units in any combination thereof. For example, receiver 105 may be a part of TV 90 or receiver 105 may be located further upstream in a distribution system, e.g., at a head-end, which then retransmits the content to other nodes and/or receivers of a network. It is therefore to be understood that numerous modifications may be made to the illustrative embodiments and that other arrangements may be devised without departing from the spirit and scope of the present invention as defined by the appended claims.

1. A method for use in a receiver, the method comprising:
receiving low density parity check (LDPC) encoded data; and
processing the received LDPC encoded data using check node messages and bit node messages to provide decoded data;
wherein the processing step manipulates a parity check matrix such that there are Y groups of bit nodes and q groups of check nodes, where q varies as a function of a code rate associated with the received LDPC encoded data.

2. The method of claim 1, wherein the received LDPC encoded data is derived from a received digital video broadcasting system-2 signal.

3. The method of claim 1, wherein the received LDPC encoded data is representative of an (N, K) LDPC code, where M=N−K, and q=Y (N−K)/N.

4. The method of claim 3, wherein Y=N/360.

5. The method of claim 1, wherein the received LDPC encoded data is representative of an (N, K) LDPC code having a parity matrix of dimensions M×N, and wherein the processing step includes:
processing each group of check node messages with J processors; and
processing each group of bit node messages with J processors;
wherein J represents dimensions of a square sub-matrix, such that an integral number of square sub-matrices fit into the parity matrix.

6. The method of claim 5, wherein the processing the check node messages step includes the steps of:
cyclically shifting each group of check node messages;
processing each cyclically shifted group of check node message with J processors to provide a group of new messages; and
cyclically shifting each group of new messages to form a group of bit node messages.

7. The method of claim 5, wherein the processing the bit node messages step includes the steps of:
cyclically shifting each group of bit node messages;
processing each cyclically shifted group of bit node message with J processors to provide a group of new messages; and
cyclically shifting each group of new messages to form a group of check node messages.

8. The method of claim 1, wherein the received LDPC encoded data is representative of an (N, K) LDPC code having a parity matrix of dimensions M×N, and wherein the processing step includes:
processing each group of check node messages with J processors; and
processing each group of bit node messages with J processors;
wherein J=N/Y.

9. The method of claim 8, wherein the processing the check node messages step includes the steps of:
cyclically shifting each group of check node messages;
processing each cyclically shifted group of check node message with J processors to provide a group of new messages; and
cyclically shifting each group of new messages to form a group of bit node messages.

10. The method of claim 8, wherein the processing the bit node messages step includes the steps of:
cyclically shifting each group of bit node messages;
processing each cyclically shifted group of bit node message with J processors to provide a group of new messages; and
cyclically shifting each group of new messages to form a group of check node messages.

11. Apparatus for use in a receiver, the apparatus comprising:
a demodulator for providing low density parity check (LDPC) encoded data;
an LDPC decoder for decoding the LDPC encoded data to provide decoded data;
wherein the LDPC decoder processes the LDPC encoded data by partitioning bit node messages into Y groups and check node messages into q groups, where q varies as a function of a code rate associated with the LDPC encoded data.

12. The apparatus of claim 11, wherein the LDPC encoded data is derived from a received digital video broadcasting system-2 signal.

13. The apparatus of claim 11, wherein the LDPC encoded data is representative of an (N, K) LDPC code, where M=N−K, and q=Y (N−K)/N.

14. The apparatus of claim 13, wherein Y=N/360.

15. The apparatus of claim 11, wherein the LDPC encoded data is representative of an (N, K) LDPC code having a parity matrix of dimensions M×N, and wherein the LDPC encoder comprises:
J processors for processing each group of bit node messages; and
J processors for processing each group of check node messages;
wherein J represents dimensions of a square sub-matrix, such that an integral number of square sub-matrices fit into the parity matrix.

16. The apparatus of claim 11, wherein the LDPC encoded data is representative of an (N, K) LDPC code having a parity matrix of dimensions M×N, and wherein the LDPC encoder comprises:
J processors for processing each group of bit node messages; and
J processors for processing each group of check node messages;
wherein J=N/Y.

17. The apparatus of claim 11, wherein the LDPC decoder comprises:
a memory for storing the check node messages and the bit node messages; and
cyclic shifter for shifting the check node messages;
a group of bit node processors for processing the cyclically shifted check node messages to provide new messages;
a cyclic shifter for shifting the new messages to form new bit node messages;
a group of check node processors for processing the bit node messages to provide new check node messages for storage in the memory,
wherein the memory is structured such that new bit node messages are stored consecutively.

18. The apparatus of claim 11, wherein the LDPC decoder comprises:
a memory for storing the check node messages and the bit node messages; and
a group of bit node processors for processing the check node messages to provide new bit node messages for storage in the memory; and
a cyclic shifter for shifting the bit node messages;
a group of check node processors for processing the cyclically shifted bit node messages to provide new messages; and
a cyclic shifter for shifting the new messages to form new check node messages;
wherein the memory is structured such that new check node messages are stored consecutively.

19. The apparatus of claim 11, wherein the LDPC decoder comprises a memory organized such that groups of bit node messages are stored consecutively.

20. The apparatus of claim 11, wherein the LDPC decoder comprises a memory organized such that groups of check node messages are stored consecutively.
